(19) United States
(12) Patent Application Publication
(10) Pub. No.: US 2026/0304768 A1
(43) Pub. Date: Oct. 1, 2026

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventor: Sang Bum LEE, Gyeonggi-do (KR)

(21) Appl. No.: 19/309,618

(22) Filed: Aug. 26, 2025

(30) Foreign Application Priority Data
Apr. 1, 2025 (KR) 10-2025-0041907

(51) Int. Cl. H10B 43/27; H10B 41/27; H10B 41/35; H10B 43/35

(52) U.S. Cl. CPC H10B 43/27; H10B 41/27; H10B 41/35; H10B 43/35

(57) ABSTRACT

A semiconductor device may include channel stacks including channel layers and insulating layers that are alternately stacked, the channel stacks including concave portions and convex portions arranged on sidewalls; insulating pillars located to correspond to the concave portions between the channel stacks; and electrode pillars located to correspond to the convex portions between the channel stacks.

### CROSS-REFERENCE TO RELATED APPLICATION

This application claims priority under 35 U.S.C. § 119 to Korean Patent Application No. 10-2025-0041907 filed on Apr. 1, 2025, which is incorporated herein by reference in its entirety.

### BACKGROUND

### 1. Technical Field

Embodiments of the present disclosure relate generally to an electronic device, and more particularly, to a semiconductor device and a method of manufacturing the semiconductor device.

### 2. Related Art

The integration density of a semiconductor device is primarily defined by the area occupied by an individual memory cell. As traditional methods of forming memory cells in a single layer on a substrate approach their scaling limits, three-dimensional semiconductor architectures that stack memory cells vertically have been introduced. Additionally, various structural designs and manufacturing techniques are being developed to enhance the operational reliability of these advanced semiconductor devices.

### SUMMARY

In an embodiment of the present disclosure, a semiconductor device may include channel stacks including channel layers and insulating layers that are alternately stacked, the channel stacks including concave portions and convex portions arranged on sidewalls; insulating pillars located to correspond to the concave portions between the channel stacks; and electrode pillars located to correspond to the convex portions between the channel stacks.

In an embodiment of the present disclosure, a semiconductor device may include a first channel stack extending in a first direction and including first channel layers and first insulating layers that are alternately stacked; a second channel stack extending in the first direction, adjacent to the first channel stack in a second direction intersecting the first direction, and including second channel layers and second insulating layers that are alternately stacked; and electrode pillars located between the first channel stack and the second channel stack and arranged along the first direction, wherein the first channel stack may include first convex portions protruding toward the second channel stack and the second channel stack may include second convex portions protruding toward the first channel stack, and each of the electrode pillars may surround the first convex portion and the second convex portion located to face each other in the second direction.

In an embodiment of the present disclosure, a method of manufacturing a semiconductor device may include forming a stack including first material layers and second material layers that are alternately stacked; forming sacrificial pillars in the stack; forming first openings between the sacrificial pillars; expanding the first openings by etching the sacrificial pillars through the first openings; forming sacrificial layers in the expanded first openings; forming second openings by removing the sacrificial pillars; forming insulating pillars in the second openings; forming third openings by removing the sacrificial layers; and forming electrode pillars in the third openings.

In an embodiment of the present disclosure, a method of manufacturing a semiconductor device may include forming a stack including first material layers and second material layers that are alternately stacked; forming insulating pillars in the stack, the insulating pillars being arranged in a first direction; forming openings between the insulating pillars adjacent to each other in the first direction; replacing the first material layers with channel layers through the openings; and forming electrode pillars in the openings.

These and other features and advantages of the embodiments of the present disclosure will become better understood from the detailed description in conjunction with the following drawings.

### BRIEF DESCRIPTION OF THE DRAWINGS

FIGS. 1A and 1B are diagrams illustrating the structure of a semiconductor device in accordance with an embodiment of the present disclosure.

FIG. 2 is a diagram illustrating the structure of a semiconductor device in accordance with an embodiment of the present disclosure.

FIGS. 3A to 3C are diagrams illustrating the structure of a semiconductor device in accordance with an embodiment of the present disclosure.

FIG. 4 is a diagram illustrating the structure of a semiconductor device in accordance with an embodiment of the present disclosure.

FIG. 5 is a diagram illustrating the structure of a semiconductor device in accordance with an embodiment of the present disclosure.

FIGS. 6A, 7A, 8A, 9A, 10A, and 11A and FIGS. 6B, 7B, 8B, 9B, 10B, and 11B are diagrams for describing a method of manufacturing a semiconductor device in accordance with an embodiment of the present disclosure.

FIG. 12 is a configuration diagram of a semiconductor device in accordance with an embodiment of the present disclosure.

FIG. 13 is a configuration diagram of a semiconductor device in accordance with an embodiment of the present disclosure.

### DETAILED DESCRIPTION

Various embodiments of the present disclosure are directed to a semiconductor device having a stable structure and improved characteristics and a method of manufacturing the semiconductor device.

By stacking memory cells in three dimensions, it is possible to improve the degree of integration of a semiconductor device. It is also possible to provide a semiconductor device having a stable structure and improved reliability.

Hereafter, embodiments in accordance with the technical spirit of the present disclosure will be described with reference to the accompanying drawings.

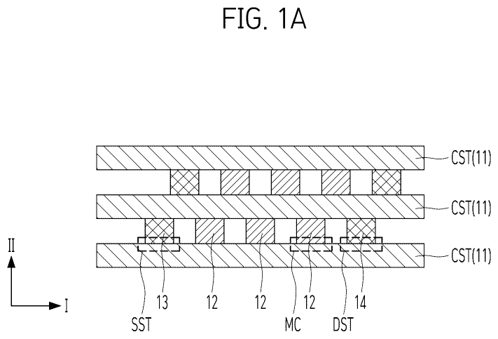

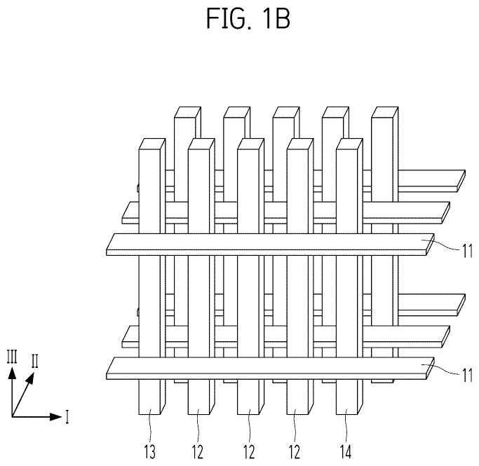

FIGS. 1A and 1B are diagrams illustrating the structure of a semiconductor device in accordance with an embodiment of the present disclosure. FIG. 1A is a layout diagram, and FIG. 1B is a perspective view.

Referring to FIGS. 1A and 1B, the semiconductor device may include channel stacks CST and electrode pillars 12 to 14.

The channel stacks CST may extend in a first direction I. The channel stacks CST may be arranged in the first direction I and a second direction II intersecting the first direction I. Each of the channel stacks CST may include stacked channel layers 11.

The electrode pillars 12 to 14 may be located between the channel stacks CST. In a plane defined by the first direction I and the second direction II, the electrode pillars 12 to 14 may be arranged along the first direction I. Between the channel stacks CST, the electrode pillars 12 to 14 may be located spaced apart from each other. In a cross section defined by the first direction I and a third direction III as shown in FIG. 1B, each of the electrode pillars 12 to 14 may extend along the third direction III.

The electrode pillars 12 to 14 may include a first electrode pillar 12, a second electrode pillar 13, and a third electrode pillar 14. The first electrode pillar 12 may be electrically connected to a word line, the second electrode pillars 13 may be electrically connected to a source select line, and the third electrode pillar 14 may be electrically connected to a drain select line. For example, a plurality of first electrode pillars 12 may be located between at least one second electrode pillar 13 and at least one third electrode pillar 14.

According to the structure described above, memory cells MC may be located in regions where the first electrode pillar 12 and the channel layers 11 intersect each other. Source select transistors SST may be located in a region where the second electrode pillar 13 and the channel layers 11 intersect each other. Drain select transistors DST may be located in a region where the third electrode pillar 14 and the channel layers 11 intersect each other. Through this, a memory string including at least one drain select transistor DST, a plurality of memory cells MC, and at least one source select transistor SST may be configured. The memory string may be arranged along the first direction I and may be stacked along the third direction III.

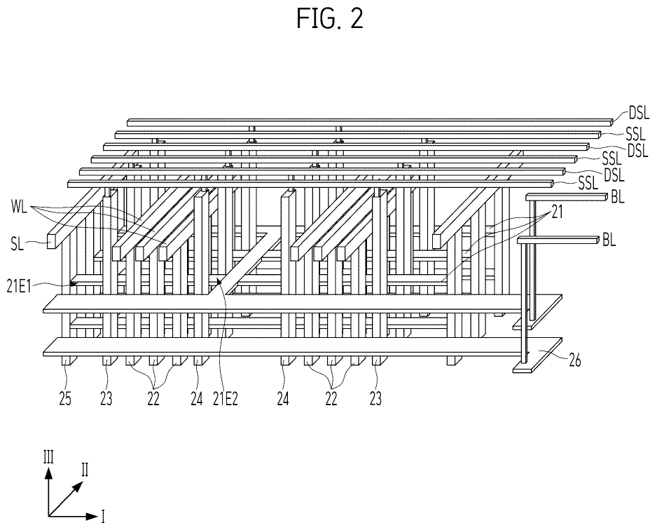

FIG. 2 is a diagram illustrating the structure of a semiconductor device in accordance with an embodiment of the present disclosure. Hereinafter, content overlapping with previously described content may be omitted.

Referring to FIG. 2, the semiconductor device may include channel layers 21, first electrode pillars 22, second electrode pillars 23, third electrode pillars 24, fourth electrode pillars 25, a word line WL, a drain select line DSL, a source select line SSL, a bit line BL, and an interconnection structure 26.

The channel layers 21 may extend in the first direction I and may be stacked in the third direction III. The channel layers 21 stacked in the third direction III may constitute one channel stack. Channel stacks may be arranged in the first direction I and the second direction II.

The first to third electrode pillars 22 to 24 may be located between the channel layers 21 adjacent to each other in the second direction II. For example, a plurality of first electrode pillars 22 may be located between at least one second electrode pillar 23 and at least one third electrode pillar 24. The second and third electrode pillars 23 and 24 may have greater height than the first electrode pillars 22. The second and third electrode pillars 23 and 24 may have substantially the same height.

The first electrode pillars 22 which are arranged along the second direction II may be connected to the word line WL. The word line WL may extend in the second direction II. The second electrode pillars 23 which are arranged along the first direction I may be connected to the source select line SSL. The third electrode pillars 24 which are arranged along the first direction I may be connected to the drain select line DSL. The source select line SSL and the drain select line DSL may be located above the word lines WL and may each extend in the first direction I.

The fourth electrode pillar 25 may be connected to one end 21E1 of the channel layers 21 and may extend in the third direction III. The fourth electrode pillars 25 may be connected to the channel stacks CST, respectively. For example, the plurality of the channel layers 21 included in the same channel stack CST may be connected to the same fourth electrode pillar 25.

A source line SL may be connected to the fourth electrode pillars 25 arranged in the second direction II and may extend in the second direction II. Through this, the channel layers 21 included in different channel stacks may be connected in common to the source line SL.

The interconnection structure 26 may connect the channel layers 21 located at the same level to each other. For example, one end 21E1 of the channel layer 21 may be connected to the fourth electrode pillar 25, and the other end 21E2 of the channel layer 21 may be connected to the interconnection structure 26. The interconnection structure 26 may include a wiring line and a via, and may be connected to the bit line BL. For example, the channel layers 21 located at the same level may be connected in common to the bit line BL through the interconnection structure 26. The channel layers 21 located at different levels may be connected to different bit lines BL.

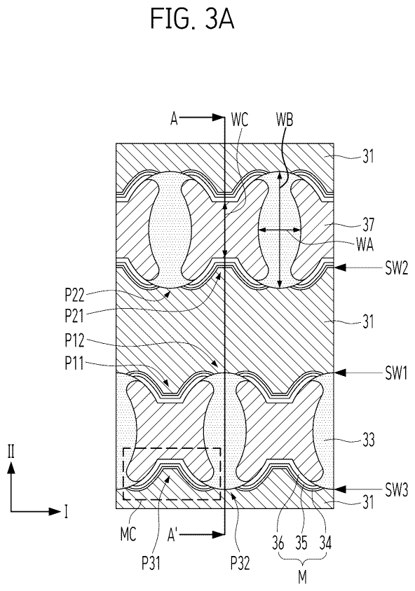

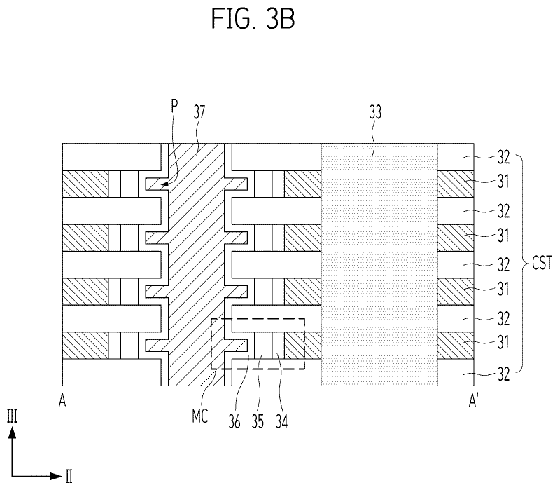

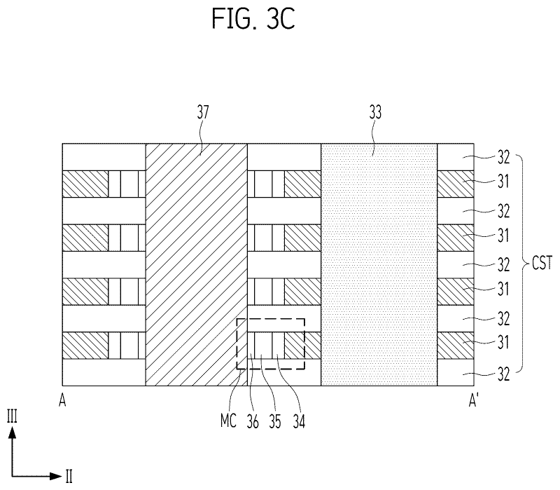

FIGS. 3A to 3C are diagrams illustrating the structure of a semiconductor device in accordance with an embodiment of the present disclosure. FIG. 3A is a plan view, and FIGS. 3B and 3C are cross-sectional views taken along line A-A′ of FIG. 3A. Hereinafter, content overlapping with previously described content may be omitted.

Referring to FIGS. 3A to 3C, the semiconductor device may include channel stacks CST, insulating pillars 33, and electrode pillars 37. The semiconductor device may further include memory layers M.

The channel stacks CST may each extend in the first direction I. The channel stacks CST may be spaced apart from each other in the second direction II as shown in FIG. 3A. Each of the channel stacks CST may include channel layers 31 and insulating layers 32 that are alternately stacked. The channel layers 31 and the insulating layers 32 may be stacked along the third direction III as shown in FIG. 3B.

In a plan view as shown in FIG. 3A, the channel stack CST may include a first sidewall SW1 and a second sidewall SW2. The first sidewall SW1 and the second sidewall SW2 may each extend in the first direction I and may face each other in the second direction II. The first sidewall SW1 may include convex portions P11 and concave portions P12 that are alternately arranged, and the second sidewall SW2 may include convex portions P21 and concave portions P22 that are alternately arranged. The convex portions P11 of the first sidewall SW1 may be located to face corresponding concave portions P22 of the second sidewall SW2. Likewise, the concave portions P12 of the first sidewall SW1 may be located to face corresponding convex portions P21 of the second sidewall SW2.

The channel stacks CST adjacent to each other in the second direction II may respectively include a first sidewall SW1 and a third sidewall SW3 facing each other in the second direction II. The convex portions P11 included in the first sidewall SW1 may protrude toward the third sidewall SW3, and convex portions P31 included in the third sidewall SW3 may protrude toward the first sidewall SW1. The convex portion P11 of the first sidewall SW1 and the convex portion P31 of the third sidewall SW3 may be located to face each other, and the concave portion P12 of the first sidewall SW1 and a concave portion P32 of the third sidewall SW3 may be located to face each other.

The insulating pillars 33 may be located to correspond to the concave portions P12, P22, and P32 between the channel stacks CST. For example, the insulating pillar 33 may be located between the concave portion P12 and the concave portion P32. The insulating pillar 33 may have a first width WA in the first direction I and may have a second width WB greater than the first width WA in the second direction II. The first width WA may be a maximum width in the first direction I, and the second width WB may be a maximum width in the second direction II.

The electrode pillars 37 may be located to correspond to the convex portions P11, P21, and P31 between the channel stacks CST. For example, the electrode pillar 37 may be located between the convex portion P11 and the convex portion P31 located to face each other, and may surround the convex portion P11 and the convex portion P31. The electrode pillars 37 may be located between the insulating pillars 33, and may be insulated from each other by the insulating pillars 33. In the second direction II, the electrode pillar 37 may have a third width WC which is narrower than the second width WB of the insulating pillar 33. The third width WC may be a maximum width in the second direction II.

The memory layers M may be located between the electrode pillars 37 and the channel layers 31. The memory layers M may surround the convex portions P11, P21, and P31, respectively. The memory layer M may include at least one of a tunneling layer 34, a data storage layer 35, and a blocking layer 36. The data storage layer 35 may include a floating gate, polysilicon, a charge trap material, nitride, a variable resistance material, or the like. The blocking layer 36 may surround a sidewall of the electrode pillar 37, the data storage layer 35 may surround the blocking layer 36, and the tunneling layer 34 may surround the data storage layer 35.

Referring to FIG. 3B, the tunneling layer 34 and the data storage layer 35 may be located between the stacked insulating layers 32. The blocking layer 36 may extend along surfaces of the insulating layers 32 and the data storage layers 35. The electrode pillar 37 may include protrusion portions P on the sidewall, and the protrusion portions P may protrude toward the channel layers 31. Referring to FIG. 3C, the tunneling layer 34, the data storage layer 35, and the blocking layer 36 may be located between the stacked insulating layers 32. The electrode pillar 37 might not include protrusion portions on the sidewall.

According to the structure described above, memory cells MC may be located in regions where the channel layers 31 and the electrode pillars 37 intersect each other. First memory cells may be located at each of the convex portions P11 of the first sidewall SW1, and second memory cells may be located at each of the convex portions P21 of the second sidewall SW2. The first memory cells may constitute a first memory string, and the second memory cells may constitute a second memory string.

Because the electrode pillars 37 surround the convex portions P11, P21, and P31, each memory cell MC may have a form in which a gate electrode surrounds the channel layer. Accordingly, program characteristics and/or erase characteristics may be improved compared to a memory cell having a form in which a channel layer surrounds a gate electrode.

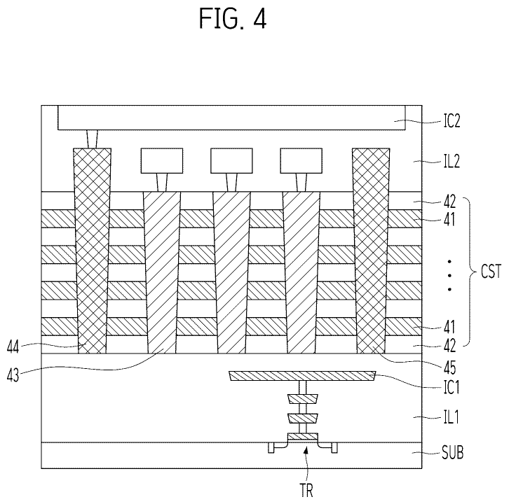

FIG. 4 is a diagram illustrating the structure of a semiconductor device in accordance with an embodiment of the present disclosure. Hereinafter, content overlapping with previously described content may be omitted.

Referring to FIG. 4, the semiconductor device may include a substrate SUB, a transistor TR, a first interconnection structure IC1, a first interlayer insulating layer IL1, a channel stack CST, a second interconnection structure IC2, and a second interlayer insulating layer IL2. A peripheral circuit may be located below a memory cell array.

The transistor TR may be located on the substrate SUB and may be part of the peripheral circuit. For example, the peripheral circuit may include a row decoder, a page buffer, an input/output circuit, a logic circuit, and the like. The first interconnection structure IC1 may be formed within the first interlayer insulating layer IL1 and may be electrically connected to the peripheral circuit. The first interconnection structure IC1 may include a via, a wiring line, and the like.

The channel stack CST may be located on the first interlayer insulating layer IL1. The channel stack CST may include channel layers 41 and insulating layers 42 that are alternately stacked. Electrode pillars 43 to 45 may be located between the channel stacks CST. For example, a plurality of first electrode pillars 43 may be located between at least one second electrode pillar 44 and at least one third electrode pillar 45. Memory cells may be located in regions where the first electrode pillars 43 and the channel layers 41 intersect each other. Source select transistors may be located in regions where the second electrode pillars 44 and the channel layers 41 intersect each other, and drain select transistors may be located in regions where the third electrode pillars 45 and the channel layers 41 intersect each other.

The second interconnection structure IC2 may be located in the second interlayer insulating layer IL2, and may be connected to the electrode pillars 43 to 45 and the like. The second interconnection structure IC2 may include a via, a wiring line, and the like. For example, the second interconnection structure IC2 may include word lines connected to the first electrode pillars 43, source select lines connected to the second electrode pillars 44, and drain select lines connected to the third electrode pillars 45.

According to the structure described above, by locating the peripheral circuit below the memory cell array, it is possible to increase the degree of integration of the semiconductor device.

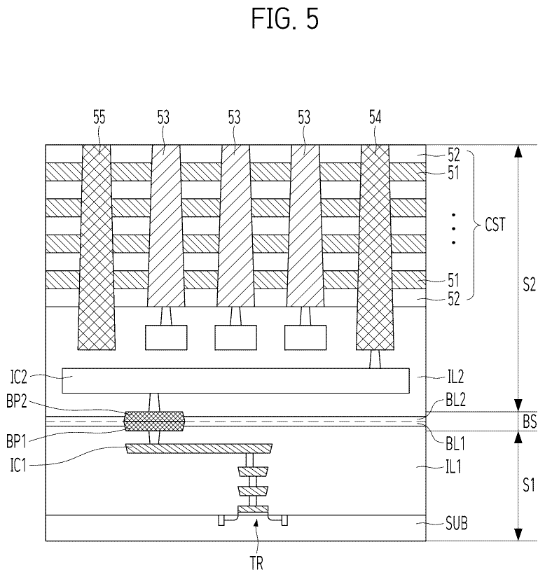

FIG. 5 is a diagram illustrating the structure of a semiconductor device in accordance with an embodiment of the present disclosure. Hereinafter, content overlapping with previously described content may be omitted.

Referring to FIG. 5, the semiconductor device may include a first semiconductor structure S1, a second semiconductor structure S2, and a bonding structure BS positioned between the first and second semiconductor structures S1 and S2. The first semiconductor structure S1 may include a peripheral circuit, and the second semiconductor structure S2 may include a memory cell array.

The first semiconductor structure S1 may include a substrate SUB, a transistor TR, a first interlayer insulating layer IL1, and a first interconnection structure IC1. The transistor TR may belong to the peripheral circuit. The first interconnection structure IC1 may be located in the first interlayer insulating layer IL1, and may include a via, a wiring line, and the like. The first interconnection structure IC1 may be electrically connected to the peripheral circuit.

The second semiconductor structure S2 may include a channel stack CST, electrode pillars 53 to 55, a second interlayer insulating layer IL2, and a second interconnection structure IC2. The channel stack CST may include channel layers 51 and insulating layers 52 that are alternately stacked. The electrode pillars 53 to 55 may be spaced apart from each other. The electrode pillars 53 to 55 may be located between the channel stacks CST. For example, a plurality of first electrode pillars 53 may be located between at least one second electrode pillar 54 and at least one third electrode pillar 55. Memory cells may be located in regions where the first electrode pillars 53 and the channel layers 51 intersect each other, source select transistors may be located in regions where the second electrode pillars 54 and the channel layers 51 intersect each other, and drain select transistors may be located in regions where the third electrode pillars 55 and the channel layers 51 intersect each other.

The second interlayer insulating layer IL2 may be located below the channel stack CST. The second interconnection structure IC2 may be located in the second interlayer insulating layer IL2, and may be connected to the electrode pillars 53 to 55 and the like. The second interconnection structure IC2 may include a via, a wiring line, and the like. For example, the second interconnection structure IC2 may include word lines connected to the first electrode pillars 53, source select lines connected to the second electrode pillars 54, and drain select lines connected to the third electrode pillars 55.

The bonding structure BS may be located between the first semiconductor structure S1 and the second semiconductor structure S2. The first semiconductor structure S1 and the second semiconductor structure S2 may be manufactured separately, and may be electrically connected to each other by the bonding structure BS. The memory cell array including gate lines GL and the peripheral circuit including the transistor TR may be electrically connected to each other through the bonding structure BS.

The bonding structure BS may include a first bonding layer BL1, a second bonding layer BL2, a first bonding pad BP1, and a second bonding pad BP2. The first bonding layer BL1 and the second bonding layer BL2 may be in contact with each other, and the first bonding pad BP1 and the second bonding pad BP2 may be in contact with each other. The first bonding layer BL1 and the second bonding layer BL2 may each include, for example, SiCN, tetra ethyl ortho silicate (TEOS), or the like. The first bonding pad BP1 may be electrically connected to the first interconnection structure IC1, and the second bonding pad BP2 may be electrically connected to the second interconnection structure IC2. The memory cell array and the peripheral circuit may be electrically connected to each other through the first bonding pad BP1 and the second bonding pad BP2.

According to the structure described above, the first semiconductor structure S1 and the second semiconductor structure S2 are bonded to each other in a vertical direction, and it is thus possible to increase the degree of integration of the semiconductor device.

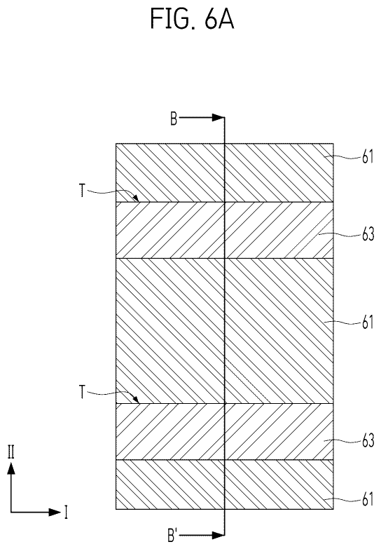

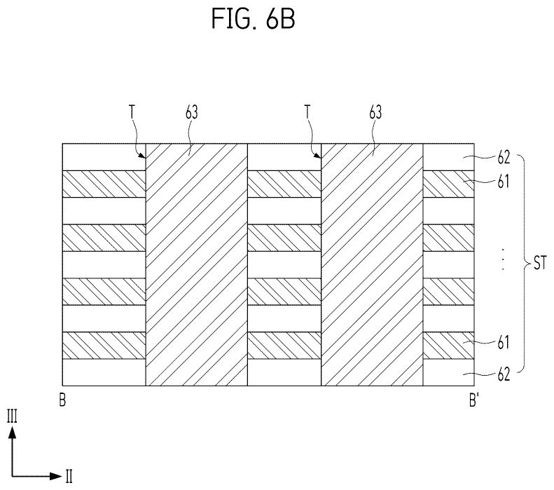

FIGS. 6A, 7A, 8A, 9A, 10A, and 11A and FIGS. 6B, 7B, 8B, 9B, 10B, and 11B are diagrams for describing a method of manufacturing a semiconductor device in accordance with an embodiment of the present disclosure. FIGS. 6A, 7A, 8A, 9A, 10A, and 11A are plan views, and FIGS. 6B, 7B, 8B, 9B, 10B, and 11B are cross-sectional views taken along lines B-B′ of 6A, 7A, 8A, 9A, 10A, and 11A, respectively. Hereinafter, content overlapping with previously described content may be omitted.

Referring to FIGS. 6A and 6B, a stack ST may be formed to include first and second material layers 61 and 62 that are alternately stacked. The first material layers 61 may be used to form channel layers. The second material layers 62 may be used to form insulating layers. Each of the first material layers 61 may include a material having a high etching selectivity with respect to the second material layers 62. For example, each of the first material layers 61 may include a sacrificial material such as a nitride, and each of the second material layers 62 may include an insulating material such as an oxide. Each of the first material layers 61 may include a semiconductor material such as polysilicon, and each of the second material layers 62 may include an insulating material such as an oxide. The first material layers 61 may each include a semiconductor material such as polysilicon, and the second material layers 62 may each include a sacrificial material such as silicon germanium.

Subsequently, a trench T may be formed in the stack ST. The trench T may extend in the first direction I. For example, a plurality of trenches T may be formed, and may be spaced apart from each other along the second direction II. Subsequently, a first sacrificial layer 63 may be formed in the trench T. The first sacrificial layer 63 may include a material having a high etching selectivity with respect to the first and second material layers 61 and 62. For example, the first sacrificial layer 63 may include a carbon-based material, and may include spin on carbon (SOC).

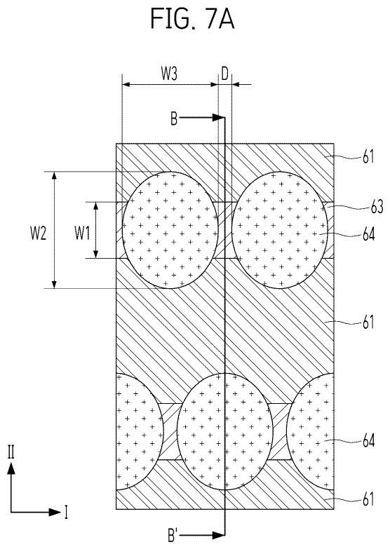

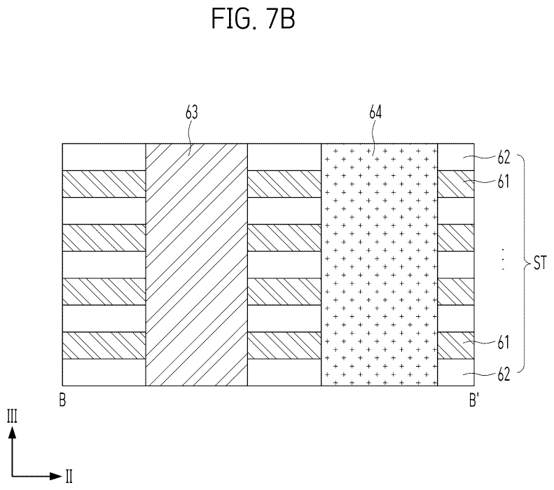

Referring to FIGS. 7A and 7B, sacrificial pillars 64 extending through the first sacrificial layer 63 may be formed. For example, openings may be formed by etching the first sacrificial layer 63, and the sacrificial pillars 64 may be formed in the openings, respectively. The sacrificial pillars 64 may each include a material having a high etching selectivity with respect to the first material layers 61, the second material layers 62, and the first sacrificial layer 63. For example, the sacrificial pillars 64 may each include polysilicon, metal, or the like.

In the plane defined by the first direction I and the second direction II, the sacrificial pillar 64 may have a shape such as a circular shape, an elliptical shape, or a polygonal shape. For example, the sacrificial pillar 64 may have an elliptical shape in which a second width W2 in the second direction II is wider than a third width W3 in the first direction I.

The sacrificial pillars 64 may be arranged in a row along the first sacrificial layer 63. In the second direction II, the second width W2 of the sacrificial pillar 64 may be wider than a first width W1 of the first sacrificial layer 63, and the sacrificial pillar 64 may protrude into the stack ST. A distance D between the sacrificial pillars 64 adjacent to each other in the first direction I may be smaller than the width W3 of the sacrificial pillar 64. The sacrificial pillars 64 may be formed at a narrow interval in consideration of increasing an interval between the sacrificial pillars 64 in a subsequent process.

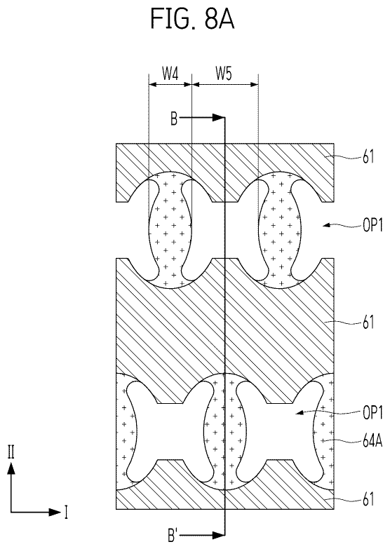

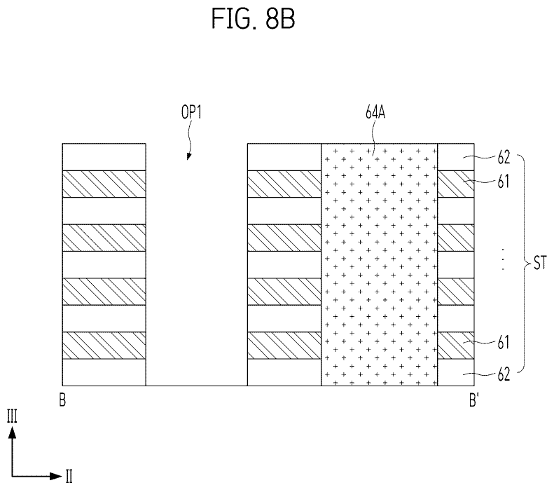

Referring to FIGS. 8A and 8B, first openings OP1 may be formed between the sacrificial pillars 64 by removing the first sacrificial layer 63. Sidewalls of the sacrificial pillars 64 may be exposed through the first openings OP1. Subsequently, the sacrificial pillars 64 may be etched through the first openings OP1. Through this, a width of the sacrificial pillar 64A in the first direction I may be reduced, and the first openings OP1 may be expanded in the first direction I. In a plan view, the etched sacrificial pillar 64A may have an I shape, and may include a curved surface on a sidewall thereof. In the first direction I, the etched sacrificial pillar 64A may have a fourth width W4, and the expanded first opening OP1 may have a fifth width W5 which is wider than the fourth width W4. By increasing a distance between adjacent sacrificial pillars 64A in the first direction I, it is possible to secure a space in which an electrode pillar is to be formed.

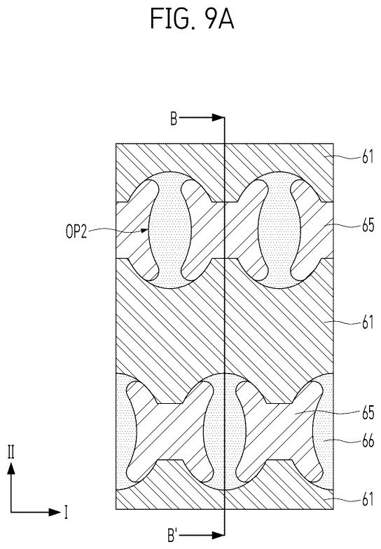

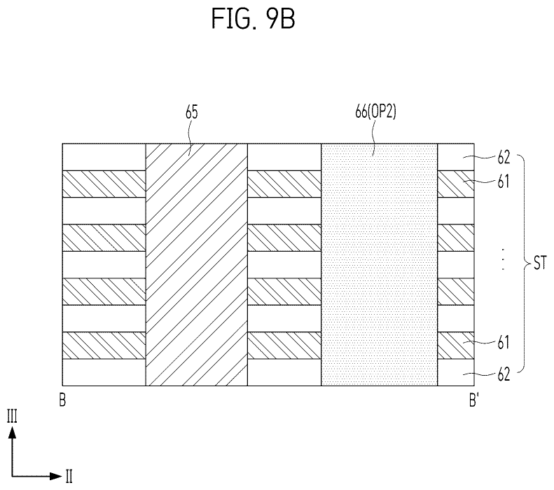

Referring to FIGS. 9A and 9B, second sacrificial layers 65 may be formed in the first openings OP1. The second sacrificial layers 65 may each include a material having a high etching selectivity with respect to the first material layers 61, the second material layers 62, and the sacrificial pillars 64A. For example, the second sacrificial layers 65 may each include a carbon-based material, and may each include spin on carbon (SOC).

Subsequently, second openings OP2 may be formed by removing the sacrificial pillars 64A. Subsequently, insulating pillars 66 may be formed in the second openings OP2. Through this, the sacrificial pillars 64A may be replaced with the insulating pillars 66, and the insulating pillars 66 may have substantially the same shape as the sacrificial pillars 64A. The insulating pillars 66 may each include an insulating material such as oxide.

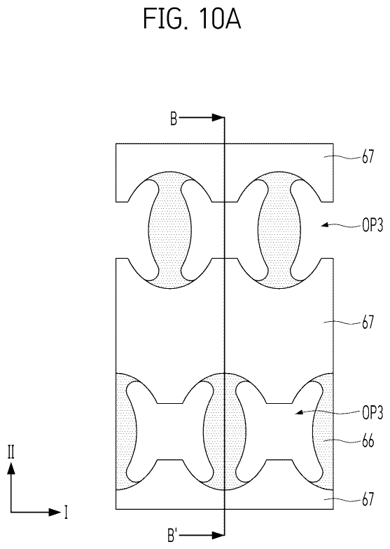

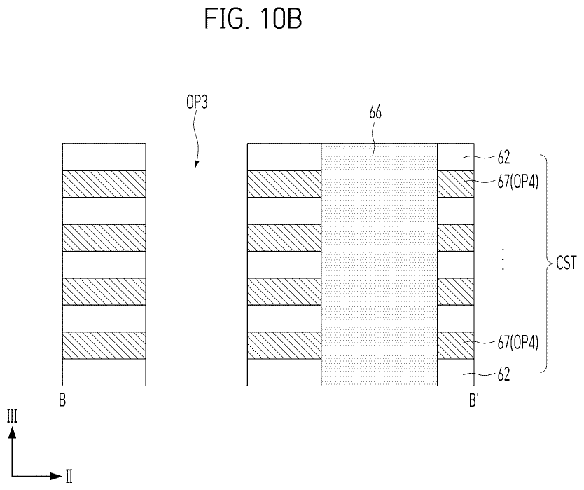

Referring to FIGS. 10A and 10B, third openings OP3 may be formed by removing the second sacrificial layers 65. The third openings OP3 may have substantially the same shape as the first openings OP1 that were previously formed. Because each insulating pillar 66 has a narrow width, each third opening OP3 can have sufficient width for forming an electrode pillar.

Subsequently, the first material layers 61 may be replaced with third material layers 67. When the first material layers 61 each include a sacrificial material, fourth openings OP4 may be formed by etching the first material layers 61, and the third material layers 67 may be formed in the fourth openings OP4. The third material layers 67 may be channel layers, and may each include a semiconductor material such as polysilicon.

For reference, when each first material layer 61 includes a semiconductor material such as polysilicon and each second material layer 62 includes an insulating material, the first material layers 61 may be used as channel layers. In such a case, a process of replacing the first material layers 61 with the third material layers 67 may be omitted. When the first material layers 61 each include a semiconductor material and the second material layers 62 each include a sacrificial material, the second material layers 62 may be replaced with third material layers. In such a case, the third material layers may be insulating layers, and may each include an insulating material such as oxide.

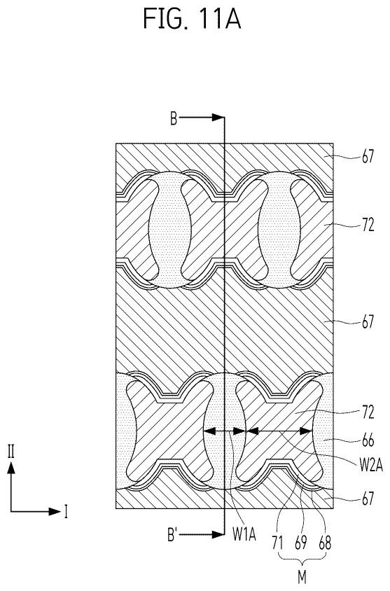

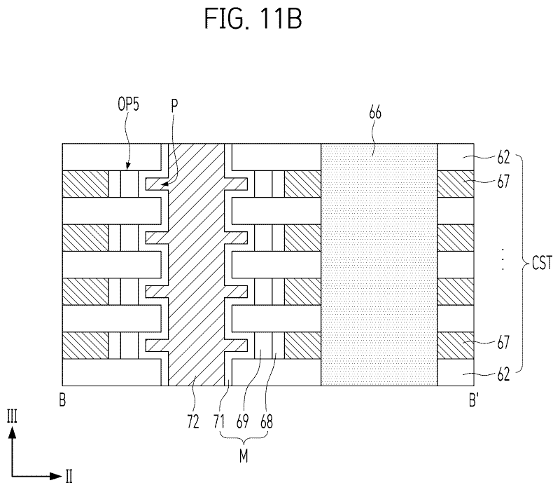

Referring to FIGS. 11A and 11B, fifth openings OP5 may be formed by etching the third material layers 67 through the third openings OP3. Subsequently, memory layers M may be formed in the fifth openings OP5. For example, tunneling layers 68 may be formed in the fifth openings OP5, data storage layers 69 may be formed on the tunneling layers 68, and a blocking layer 71 may be formed on the data storage layers 69. The tunneling layers 68 and the data storage layers 69 may be located in the fifth openings OP4, and may be separated from each other by the stacked second material layers 62. The blocking layer 71 may be formed along surfaces of the second material layers 62 and the data storage layers 69, and may be formed in the third openings OP3 and the fourth openings OP4. For reference, it is also possible for the blocking layers 71 to be formed in the fifth openings OP5 and to be separated from each other by the stacked second material layers 62.

Subsequently, electrode pillars 72 may be formed in the third openings OP3. The electrode pillars 72 may include protrusion portions P on sidewalls thereof, and the protrusion portions P may protrude toward the third material layers 67. For reference, the fifth openings OP5 may be completely filled by the memory layers M, and the electrode pillars 72 may not include the protrusion portions on the sidewalls thereof.

In the first direction I, the insulating pillar 66 may have a first width W1A, and the electrode pillar 72 may have a second width W2A that is wider than the first width W1A. The first width W1A may correspond to the maximum width of the insulating pillar 66, and the second width W2A may correspond to the minimum width of the electrode pillar 72. The first width W1A may be a distance between the electrode pillars 72 adjacent to each other in the first direction I. Accordingly, the distance between the electrode pillars 72 adjacent to each other in the first direction I may be smaller than the width W2A of the electrode pillar 72.

According to the method described above, by etching the sacrificial pillars 64 through the first openings OP1, it is possible to reduce the width of the sacrificial pillars 64. This process enables the formation of insulating pillars 66 having a narrow width, and allows for a reduced distance between the electrode pillars 72, while securing the spaces needed for the electrode pillars 72 to be formed. As a result, the cell area can be minimized, enhancing the integration density of the semiconductor device.

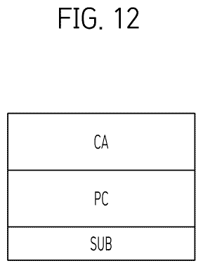

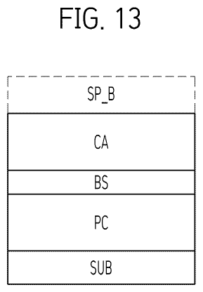

The structures and the method according to the above-described embodiments may be applied to semiconductor devices having various structures. FIGS. 12 and 13 illustrate schematic configurations of semiconductor devices to which the above-described embodiments are applicable.

FIG. 12 is a configuration diagram of a semiconductor device in accordance with an embodiment of the present disclosure.

Referring to FIG. 12, the semiconductor device may include a substrate SUB, a peripheral circuit PC, and a memory cell array CA. Here, the peripheral circuit PC and the memory cell array CA may be formed on the same substrate.

The substrate SUB may include a semiconductor material. For example, the semiconductor material may include at least one of a group IV semiconductor, a group III-V compound semiconductor, and a group II-VI compound semiconductor. Here, the group IV semiconductor may include single crystal silicon (Si), polycrystalline silicon, germanium (Ge), or silicon germanium (SiGe). The group III-V compound semiconductor may include GaAs, GaN, GaP, GaAsP, GaInAsP, AlAs, AlGa, InP, InSb, or InGaAs. The group II-VI compound semiconductor may include ZnS, ZnO, or CdS.

The substrate SUB may include a dielectric layer. The substrate SUB may be a silicon-on-insulator (SOI) substrate, a germanium-on-insulator (GeOI) substrate, or a glass substrate. The substrate SUB may include an organic material. For example, the substrate SUB may include graphene.

The substrate SUB may be a bulk wafer or an epitaxial layer grown by a selective epitaxial growth (SEG) method. The substrate SUB may be a layer formed by a metal induced lateral crystallization (MILC) method, and may partially include metal. The substrate SUB may have a single crystalline, polycrystalline, or amorphous state. The substrate SUB may include group II, group III, group IV, group V, or group VI impurities. For example, the substrate SUB may include an n-well region doped with n-type impurities and/or a p-well region doped with p-type impurities.

The peripheral circuit PC may be located between the substrate SUB and the memory cell array CA. The peripheral circuit PC may include a row decoder, a column decoder, a page buffer, a logic circuit, a control circuit, a sense amplifier, an input/output circuit, and the like. For example, the peripheral circuit PC may include an N-channel metal oxide semiconductor (NMOS) transistor, a P-channel metal oxide semiconductor (PMOS) transistor, a resistor, a capacitor, and the like. The peripheral circuit PC may further include an interconnection structure. The interconnection structure may be used as a path for transmitting an operation voltage, and may include a contact plug, a wiring line, and the like.

The memory cell array CA may include memory cells. For example, the memory cell array CA may include memory strings connected between a source line and a bit line, and each memory string may include stacked memory cells. For example, the memory cell array CA may include memory cells connected between a word line and the bit line. The memory cell array CA may further include an interconnection structure.

FIG. 13 is a configuration diagram of a semiconductor device in accordance with an embodiment of the present disclosure.

Referring to FIG. 13, the semiconductor device may include a substrate SUB, a peripheral circuit PC, a bonding structure BS, and a memory cell array CA. Here, the peripheral circuit PC and the memory cell array CA may be formed on separate substrates, respectively, and then bonded to each other. The semiconductor device may further include a support base SP_B.

The substrate SUB may be used as a support in a process of forming the peripheral circuit PC. The support base SP_B may be used as a support in a process of forming the memory cell array CA. For example, a first wafer including the memory cell array CA and a second wafer including the peripheral circuit PC may be manufactured, respectively, and then electrically connected to each other by the bonding structure BS. After the first wafer and the second wafer are bonded to each other, the support base SP_B of the first wafer may be at least partially removed. The support base SP_B may be completely removed or may partially remain on the memory cell array CA.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown by a selective epitaxial growth (SEG) method, or a layer formed by a metal induced lateral crystallization (MILC) method. The support base SP_B may have a single crystalline, polycrystalline, or amorphous state. The support base SP_B may include group II, group III, group IV, group V, or group VI impurities.

The bonding structure BS may be used to connect the memory cell array CA and the peripheral circuit PC to each other. For example, the bonding structure BS may bond the memory cell array CA and the peripheral circuit PC to each other by a wafer-on-wafer bonding method, a chip-on-wafer bonding method, a chip-on-chip bonding method, or the like. The bonding structure BS may include a bonding pad, a bonding layer, a bonding interface, and the like. The bonding pad may include metal such as copper or aluminum and/or alloys thereof. The bonding interface may include a nonmetal-nonmetal interface, a metal-metal interface, or the like. The memory cell array CA and the peripheral circuit PC may be electrically connected to each other by the bonding structure BS.

For reference, it is also possible for interconnection structures included in the memory cell array CA and/or the peripheral circuit PC to be directly connected to each other without a bonding pad. For example, a bonding layer included in the memory cell array CA and a bonding layer included in the peripheral circuit PC may be bonded to each other to form a bonding interface, and an interconnection structure included in the memory cell array CA and an interconnection structure included the peripheral circuit PC may be directly connected to each other. Through this, contact plugs, wiring lines, and the like, formed on different wafers may be electrically connected to each other without a separate bonding pad.

Other configurations may be the same as or similar to those described above with reference to FIG. 12.

Moreover, it is also possible for the semiconductor device to have a structure in which embodiments described above with reference to FIGS. 12 and 13 combine with each other or have a partially modified structure. In embodiments described with reference to FIGS. 12 and 13, locations of the memory cell array CA and the peripheral circuit PC may be changed. At least one memory cell array CA and/or at least one peripheral circuit PC may be additionally bonded in embodiments described with reference to FIGS. 12 and 13. For example, a portion of the peripheral circuit PC may be located in the memory cell array CA.

Although embodiments according to the technical idea of the present disclosure have been described above with reference to the accompanying drawings, this is only for illustrating the embodiments according to the concept of the present disclosure, and the present disclosure is not limited to the above embodiments. Various types of substitutions, modifications, changes, and combinations for the embodiments may be made by those skilled in the art, to which the present disclosure pertains, without departing from the embodiments defined in the following claims, and it should be construed that these substitutions, modifications, changes, and combinations belong to the scope of the present disclosure.

What is claimed is:

1. A semiconductor device comprising:
channel stacks including channel layers and insulating layers that are alternately stacked, the channel stacks including concave portions and convex portions arranged on sidewalls;
insulating pillars located to correspond to the concave portions between the channel stacks; and
electrode pillars located to correspond to the convex portions between the channel stacks.

2. The semiconductor device of claim 1, wherein the channel stacks extend in a first direction, and the insulating pillars and the electrode pillars are located between the channel stacks adjacent to each other in a second direction intersecting the first direction.

3. The semiconductor device of claim 2, wherein the concave portions and the convex portions are alternately arranged on the sidewalls of the channel stacks along the first direction.

4. The semiconductor device of claim 2, wherein each of the channel stacks includes a first sidewall and a second sidewall facing each other in the second direction, and the convex portions of the first sidewall are located to face the concave portions of the second sidewall.

5. The semiconductor device of claim 2, wherein each of the insulating pillars has a first width in the first direction and has a second width wider than the first width in the second direction.

6. The semiconductor device of claim 5, wherein a distance between the electrode pillars adjacent to each other in the first direction is smaller than the first width of each of the electrode pillars in the first direction.

7. The semiconductor device of claim 1, wherein the electrode pillars surround the convex portions, respectively.

8. The semiconductor device of claim 1, further comprising memory layers surrounding the convex portions, respectively, and located between the channel layers and the electrode pillars.

9. The semiconductor device of claim 8, wherein each of the memory layers comprises:
a blocking layer surrounding the electrode pillar;
a data storage layer surrounding the blocking layer; and
a tunneling layer surrounding the data storage layer.

10. The semiconductor device of claim 9, wherein the data storage layer and the tunneling layer are located between the stacked insulating layers.

11. The semiconductor device of claim 1, wherein each of the electrode pillars includes protrusion portions on a sidewall thereof, the protrusion portions protruding toward the channel layers.

12. The semiconductor device of claim 1, wherein memory cells are located in regions where the channel layers and the electrode pillars intersect each other.

13. A semiconductor device comprising:
a first channel stack extending in a first direction and including first channel layers and first insulating layers that are alternately stacked;
a second channel stack extending in the first direction, adjacent to the first channel stack in a second direction intersecting the first direction, and including second channel layers and second insulating layers that are alternately stacked; and
electrode pillars located between the first channel stack and the second channel stack and arranged along the first direction,
wherein the first channel stack includes first convex portions protruding toward the second channel stack and the second channel stack includes second convex portions protruding toward the first channel stack, and
each of the electrode pillars surrounds the first convex portion and the second convex portion located to face each other in the second direction.

14. The semiconductor device of claim 13, further including insulating pillars located between the electrode pillars,
wherein in the first direction, a width of each of the insulating pillars is narrower than a width of each of the electrode pillars.

15. The semiconductor device of claim 13, further comprising:
first memory layers located between the first convex portions and the electrode pillars; and
second memory layers located between the second convex portions and the electrode pillars.

16. The semiconductor device of claim 13, wherein first memory cells are located in regions where the first channel layers and the electrode pillars intersect each other, and
second memory cells are located in regions where the second channel layers and the electrode pillars intersect each other.

17. The semiconductor device of claim 13, wherein the electrode pillars comprise:
first electrode pillars connected to a word line;
second electrode pillars connected to a source select line; and
third electrode pillars connected to a drain select line.
